(19) United States
(12) Patent Application Publication
(10) Pub. No.: US 2022/0165318 A1
(43) Pub. Date: May 26, 2022

(54) AUTOMATIC SERIAL BUS EQUALIZATION TRIM

(71) Applicant: TEXAS INSTRUMENTS INCORPORATED, Dallas, TX (US)

(72) Inventors: Mayank GARG, Ambala City (IN); Srijan RASTOGI, Bengaluru (IN); Vivekkumar Ramanlal VADODARIYA, Bengaluru (IN); Nitesh KEKRE, Bengaluru (IN)

(21) Appl. No.: 16/953,602

(22) Filed: Nov. 20, 2020

(51) Int. Cl. G11C 7/22; G11C 7/10; G11C 7/20

(52) U.S. Cl. CPC G11C 7/222; G11C 7/1078; G11C 2207/2254; G11C 7/20; G11C 7/1051

(57) ABSTRACT

A serial bus equalization trim circuit includes a first data input terminal, a second data input terminal, a delay circuit, and a flip-flop. The delay circuit includes a data input, a trim input, and an output. The data input is coupled the first data input terminal. The flip-flop includes a data input, a clock input, and an output. The data input is coupled to the output of the delay circuit. The clock input is coupled to the second data input terminal. The output is coupled to the trim input of the delay circuit.

### BACKGROUND

Serial buses, such as the Universal Serial Bus (USB), are widely used to connect systems of devices. For example, USB is used to connect devices in automotive applications. In such applications, USB data signals may be routed over relatively long lengths of cabling (e.g., >5 meters).

### SUMMARY

A serial bus equalization trim circuit is disclosed herein. In one example, a serial bus equalization trim circuit includes a first data input terminal, a second data input terminal, a delay circuit, and a flip-flop. The delay circuit includes a data input, a trim input, and an output. The data input is coupled the first data input terminal. The flip-flop includes a data input, a clock input, and an output. The data input is coupled to the output of the delay circuit. The clock input is coupled to the second data input terminal. The output of the flip-flop is coupled to the trim input of the delay circuit.

In another example, a serial bus repeater circuit includes a receiver circuit and a serial bus equalization trim circuit. The receiver circuit includes an equalizer circuit and an amplifier. The equalizer circuit includes a trim input. The amplifier is coupled to the equalizer circuit. The amplifier includes a first output and a second output. The serial bus equalization trim circuit includes a first data input terminal, a second data input terminal, and an output. The first data input terminal is coupled to the first output of the amplifier. The second data input terminal is coupled to the second output of the amplifier. The output of the serial bus equalization trim circuit is coupled to the trim input of the equalizer circuit. Some implementations of the serial bus repeater circuit include a transmitter circuit that includes a first input, a second input, and a trim input. The first input of the transmitter circuit is coupled to the first output of the amplifier. The second input of the transmitter circuit is coupled to the second output of the amplifier. The trim input is coupled to the output of the serial bus equalization trim circuit to control a width of post cursor emphasis.

In a further example, a serial bus signal conditioner circuit includes a first serial bus terminal, a second serial bus terminal, an edge detector circuit, a booster circuit, and a serial bus equalization trim circuit. The edge detector circuit includes a first input, a second input, a first output, and a second output. The first input is coupled to the first serial bus terminal. The second input is coupled to the second serial bus terminal. The booster circuit includes a first input, a second input, a first output, a second output, and a trim input. The first input of the booster circuit is coupled to the first output of the edge detector circuit. The second input of the booster circuit is coupled to the second output of the edge detector circuit. The first output of the booster circuit is coupled to the first serial bus terminal. The second output of the booster circuit is coupled to the second serial bus terminal. The serial bus equalization trim circuit includes a first data input terminal, a second data input terminal, and an output. The first data input terminal is coupled to the first output of the edge detector circuit. The second data input terminal is coupled to the second output of the edge detector circuit. The output of the serial bus equalization trim circuit is coupled to the trim input of the booster circuit.

### BRIEF DESCRIPTION OF THE DRAWINGS

For a detailed description of various examples, reference will now be made to the accompanying drawings in which:

FIG. 1 shows a block diagram for an example serial bus system that includes a repeater.

FIG. 2 shows a block diagram for an example serial bus system that includes a signal conditioner.

FIG. 3 shows an example synchronization field provided at the start of a packet transmission in a serial bus system.

FIG. 4 shows a block diagram for an example serial bus repeater circuit that includes a serial bus equalization trim circuit.

FIG. 5 shows a block diagram for an example serial bus signal conditioner circuit that includes a serial bus equalization trim circuit.

FIG. 6 shows a block diagram for an example serial bus equalization trim circuit.

FIG. 7 shows example relationships of synchronization field signals.

FIG. 8 shows an example of operation of the serial bus equalization trim circuit of FIG. 6.

FIGS. 9A-9D show a comparison of signal eyes produced by signal conditioner circuits with and without the serial bus equalization trim circuit of FIG. 6.

FIG. 10 show a flow diagram for an example method for trimming serial bus equalization.

### DETAILED DESCRIPTION

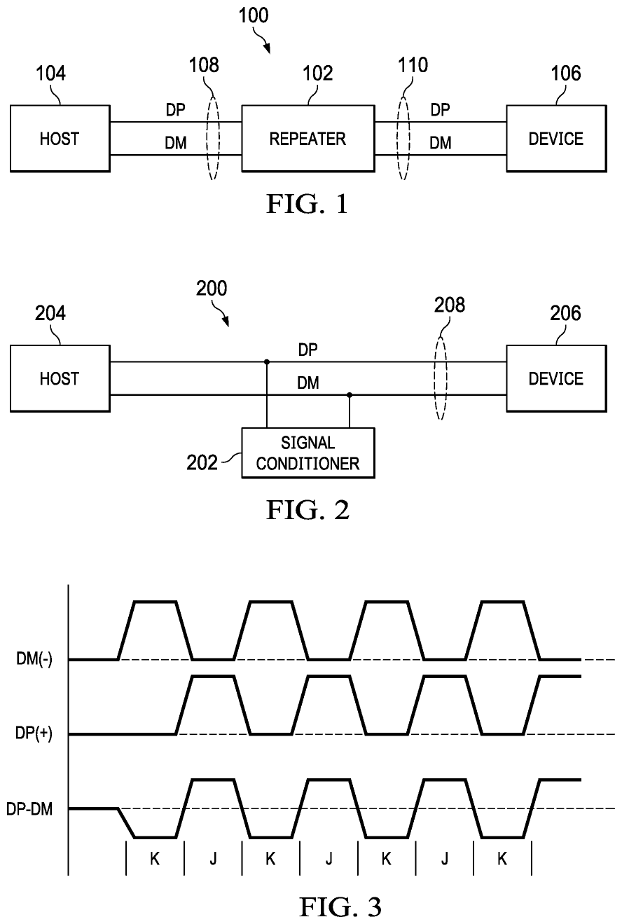

Serial bus systems, such as universal serial bus (USB) systems, use clock-less repeaters and/or signal conditioners to compensate for channel loss. FIG. 1 shows a block diagram for a serial bus system 100 that includes a repeater 102. The repeater 102 receives signals transmitted by the host 104, via the cable segment 108, and retransmits the signals to the device 106 via the cable segment 110. Similarly, the repeater 102 receives signals transmitted by the device 106, via the cable segment 110, and retransmits the signals to the host 104 via the cable segment 108. The repeater 102 includes transmitters and receivers that apply equalization to compensate for channel loss. The amount of equalization applied varies with process and temperature (e.g., 30% variation is some implementations), and can lead to yield loss if trimming is not applied. However, trimming at manufacture increases device cost due to trim time and additional circuitry (non-volatile memory) needed to store trim values.

Signal conditioners re-drive high-speed serial bus signals. FIG. 2 shows a block diagram for a serial bus system 200 that includes a signal conditioner 202. The signal conditioner 202 includes an edge detector circuit that identifies edges, on the cable 208, of signals transmitted by the or the device 206. A booster circuit of the signal conditioner 202 sources or sinks current at each edge to reduce rise or fall time. In the signal conditioner 202, edge boost pulse width is asynchronously determined using an R*C delay. Boost pulse width variation (up to 30% in some implementations) leads to eye mask failures across process and temperature corners.

To improve performance and reduce cost of serial bus repeaters and signal conditioners, the serial bus equalization trim circuit described herein provides for run-time adjustment of R*C delays that allows serial bus repeaters and signal conditioners to maintain constant equalization over process and temperature.

In serial protocols, such as USB 2.0, each packet begins with a synchronization (SYNC) field, which is a coded sequence that generates a maximum edge transition density. FIG. 3 shows an example SYNC field. The SYNC field includes at least 5 KJ pairs followed by 2K. That is, a minimum of 12 sync bits are transmitted at the start of each packet. The serial bus equalization trim circuit disclosed herein uses the SYNC field to trim the R*C product for maintaining a constant equalization over process and temperature.

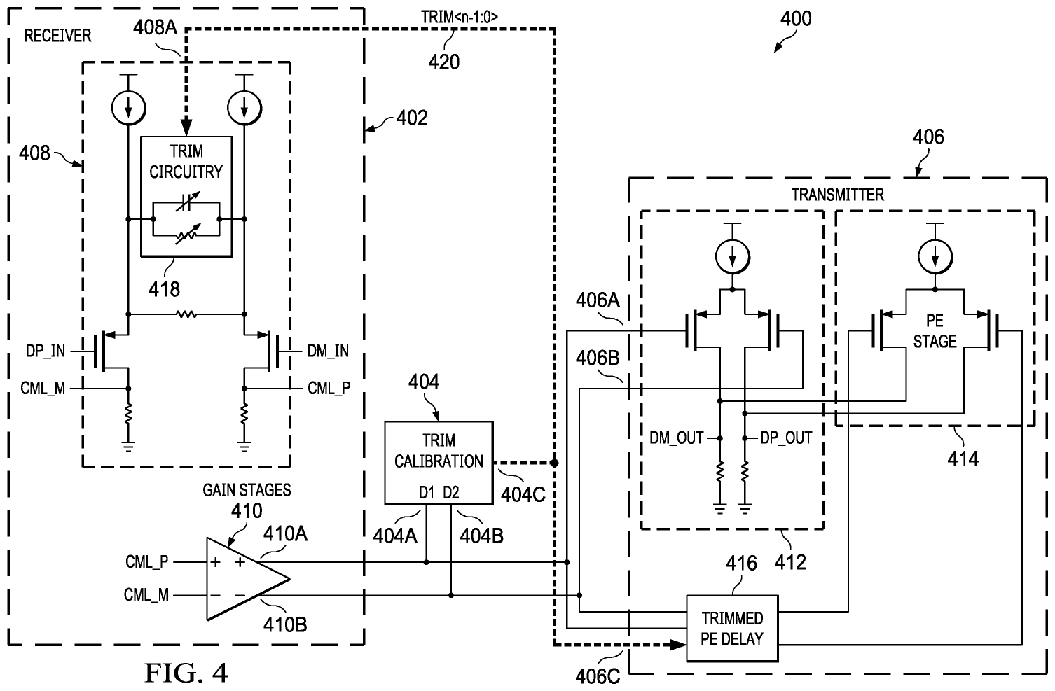

FIG. 4 shows a block diagram for an example serial bus repeater circuit 400. The serial bus repeater circuit 400 is an implementation of one path (e.g., a path from the cable segment 108 to the cable segment 110) of the repeater 102. The serial bus repeater circuit 400 includes a receiver circuit 402, a serial bus equalization trim circuit 404, and a transmitter circuit 406. The receiver circuit 402 receives signals from the cable segment 108, and the transmitter circuit 406 retransmits the received signals onto the cable segment 110.

The receiver circuit 402 includes an equalizer circuit 408 and an amplifier 410. The equalizer circuit 408 is a continuous time linear equalizer in some implementations of the equalizer circuit 408. The equalizer circuit 408 compensates for inter-symbol interference (ISI) due to the cable segment 108. The amount of equalization provided by the equalizer circuit 408 is directly proportional to R*C product which varies over process and temperature. The equalizer circuit 408 includes trim circuitry 418 that allows for adjustment of capacitance and/or resistance for equalization trim. The equalizer circuit 408 includes a trim input 408A for receiving a trim control signal 420 generated by the serial bus equalization trim circuit 404 to adjust the equalization provided by the equalizer circuit 408.

The amplifier 410 is coupled to the equalizer circuit 408, and applies gain to the equalized signal received from the equalizer circuit 408. The amplifier 410 includes an output 410A and an output 4106.

The serial bus equalization trim circuit 404 is coupled to the amplifier 410, and controls equalization in the serial bus repeater circuit 400 based on the amplified output of the equalizer circuit 408 received from the amplifier 410. The serial bus equalization trim circuit 404 includes a data input terminal 404A coupled to the output 410A of the amplifier 410, and a data input terminal 404B coupled to the output 410B of the amplifier 410. An output 404C of the serial bus equalization trim circuit 404 is coupled to the trim input 408A of the equalizer circuit 408.

The transmitter circuit 406 is coupled to the receiver circuit 402 and the serial bus equalization trim circuit 404. The transmitter circuit 406 applies post-cursor emphasis to compensate for ISI on the cable segment 110. The amount of equalization provided by the transmitter circuit 406 is directly proportional to R*C product which varies over process and temperature. The transmitter circuit 406 includes a driver circuit 412, a post-cursor emphasis (PE) circuit 414, a PE delay trim circuit 416. An input 406A of the transmitter circuit 406 is coupled to the output 410A of the amplifier 410, and an input 406B of the transmitter circuit 406 is coupled to the output 410B of the amplifier 410. A trim input 406C of the transmitter circuit 406 is coupled to the output 404C of the serial bus equalization trim circuit 404 for receipt of the trim control signal 420. The PE delay trim circuit 416 provides adjustable delay that is controllable by the trim control signal 420 to adjust the delay and set the width of post-cursor emphasis provided by the transmitter circuit 406.

The serial bus equalization trim circuit 404 is coupled to the amplifier 410, the PE delay trim circuit 416, and the trim circuitry 418. The serial bus equalization trim circuit 404 controls equalization in the serial bus repeater circuit 400 based on the amplified output of the equalizer circuit 408 received from the amplifier 410. The serial bus equalization trim circuit 404 includes a data input terminal 404A coupled to the output 410A of the amplifier 410, and a data input terminal 404B coupled to the output 410B of the amplifier 410. An output 404C of the serial bus equalization trim circuit 404 is coupled to the trim input 408A of the equalizer circuit 408 and the trim input 406C of the transmitter circuit 406. Further explanation of the serial bus equalization trim circuit 404 is provided with reference to FIGS. 6-8.

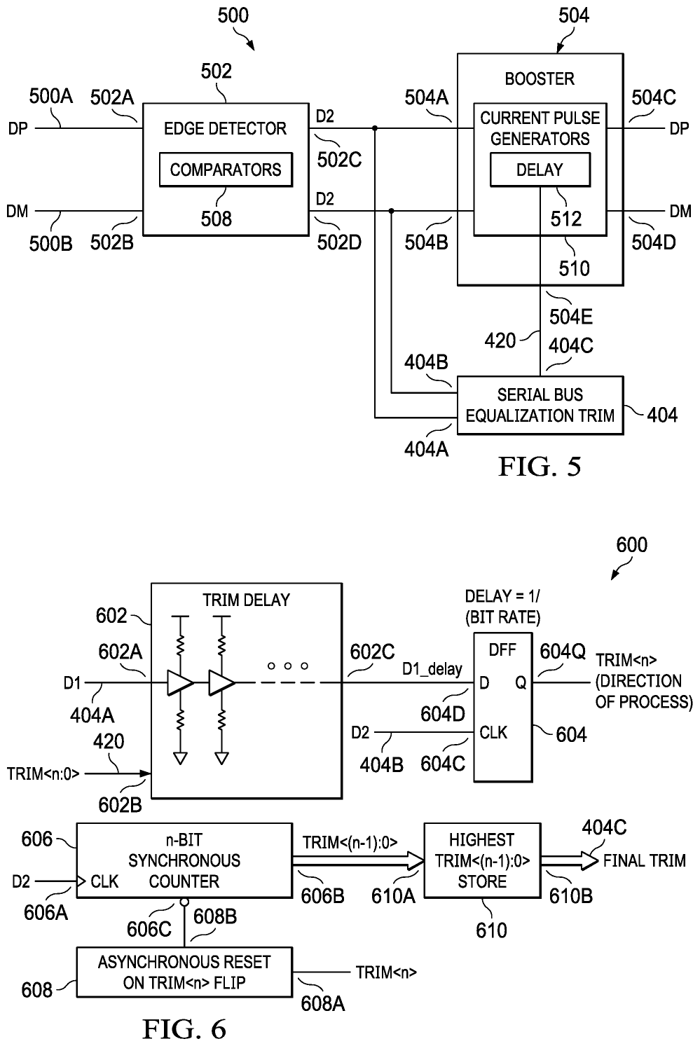

FIG. 5 shows a block diagram for an example serial bus signal conditioner circuit 500. The serial bus signal conditioner circuit 500 is an implementation of the signal conditioner 202. The serial bus signal conditioner circuit 500 includes an edge detector circuit 502, a booster circuit 504, and the serial bus equalization trim circuit 404. The serial bus signal conditioner circuit 500 includes a serial bus terminal 500A and a serial bus terminal 500B for receiving serial bus signals from the cable 208. The edge detector circuit 502 includes an input 502A coupled to the serial bus terminal 500A and an input 502B coupled to the serial bus terminal 500B. The serial bus signal conditioner circuit 500 includes comparators 508 that compare the voltages received at the input 502A and the input 502B to threshold voltages to identify transitions.

The booster circuit 504 includes a data input terminal 504A coupled to an output 502C of the edge detector circuit 502, and a data input terminal 504B coupled to an output 502D of the edge detector circuit 502. An output 504C of the booster circuit 504 is coupled to the serial bus terminal 500A, and an output 504D of the booster circuit 504 is coupled to the serial bus terminal 500B. The booster circuit 504 includes current pulse generators 510 that generate and apply current pulses to the cable 208 based on the edges detected by the edge detector circuit 502. The current pulse generators 510 includes delay circuits 512 that set the width of the current pulses. A trim input 504E of the booster circuit 504 provides the trim control signal 420 to an input 512A of the delay circuits 512 for controlling the delay of the delay circuits 512, thereby setting the width of the current pulses.

The serial bus equalization trim circuit 404 is coupled to the edge detector circuit 502 and the booster circuit 504. The serial bus equalization trim circuit 404 generates the trim control signal 420 based on the transitions of the signal received at the serial bus terminal 500A and the serial bus terminal 500B as identified by the edge detector circuit 502. The data input terminal 404A of the serial bus equalization trim circuit 404 is coupled to the output 502C of the edge detector circuit 502, and the data input terminal 404B of the serial bus equalization trim circuit 404 is coupled to the output 502D of the edge detector circuit 502. The output 404C of the serial bus equalization trim circuit 404 is coupled to the trim input 504E of the booster circuit 504.

FIG. 6 shows a block diagram for an example serial bus equalization trim circuit 600. The serial bus equalization trim circuit 600 is an implementation of the serial bus equalization trim circuit 404. The serial bus equalization trim circuit 600 includes a delay circuit 602, a flip-flop 604, a counter circuit 606, a reset circuit 608, and a trim storage register 610. The delay circuit 602 includes a data input 602A and a trim input 602B. The data input 602A is coupled to the data input terminal 404B. The delay circuit 602 includes delay elements that are controllable to vary the delay of signal received at the data input 602A passed through the delay circuit 602. The delay of the delay circuit 602 is set by the trim control signal 420 received at the trim input 602B. The delay circuit 602 includes capacitors and/or resistors that are selectable by the trim control signal 420 to set the delay of the delay circuit 602 in some implementations.

The flip-flop 604 is coupled to the delay circuit 602. A data input 604D of the flip-flop 604 is coupled to the output 602C of the delay circuit 602 for receipt of the delayed signal generated by the delay circuit 602. A clock input 604C of the flip-flop 604 is coupled to the data input terminal 404B. The delayed signal generated by the delay circuit 602 is clocked into the flip-flop 604 by the signal at the data input terminal 404B. The signals at the data input terminal 404A (D1)and the data input terminal 404B (D2) correspond to the complementary signals of the SYNC field shown in FIG. 3. The flip-flop 604 includes an output 604Q.

Ideally, the delay circuit 602 delays the signal D1 by one-half cycle so that the rising edge of the delayed signal D1 output by the delay circuit 602 aligns with the rising edge of the signal D2 received at the data input terminal 404B. If the delay provided by the delay circuit 602 is greater than one-half cycle, then the Trim<n> signal provided at the output 604Q of the flip-flop 604 is a low signal. If the delay provided by the delay circuit 602 is less than one-half cycle, then the Trim<n> signal provided at the output 604Q of the flip-flop 604 is a logic high signal. Thus, the Trim<n> signal (delay direction signal) provided at the 604Q defines the direction of delay adjustment applied in the delay circuit 602. For example, if Trim<n> is a logic low signal, then the delay of the delay circuit 602 too great and is to be reduced, and if the Trim<n> is a logic high signal, then the delay of the delay circuit 602 is too small and the delay is to be increased.

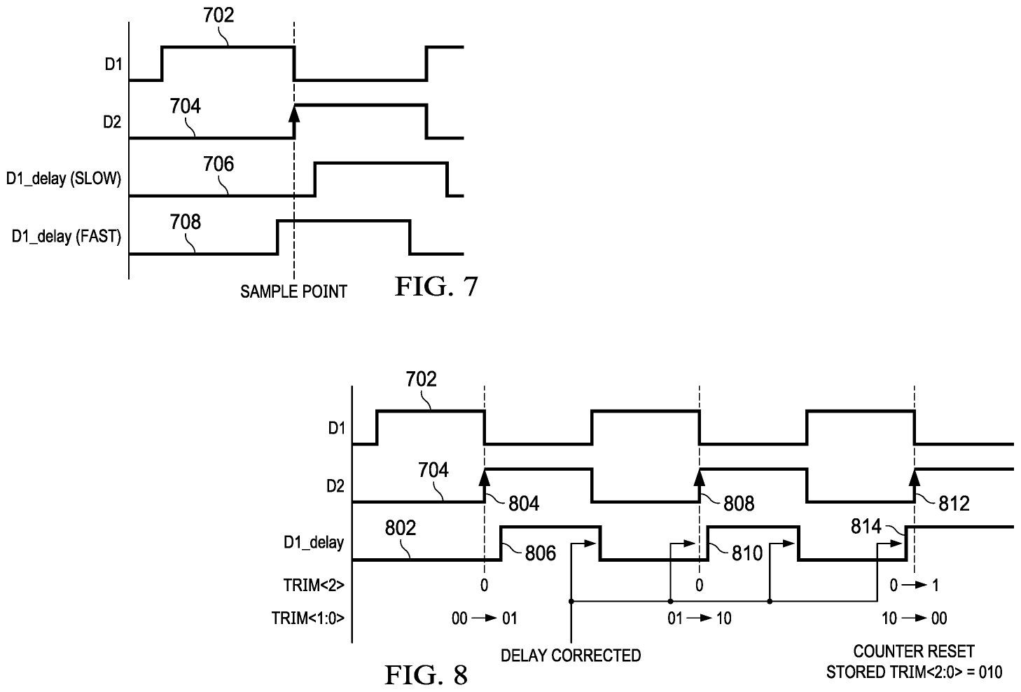

FIG. 7 shows example relationships of delayed D1 and D2. In FIG. 7, the signals 702 and 704 represent the complementary signals D1 and D2 at the data input terminal 404A and the data input terminal 404B. The signal 706 represents the delayed signal D1 generated by the delay circuit 602 if the delay of the delay circuit 602 is greater than one-half cycle. The signal 708 represents the delayed signal D1 generated by the delay circuit 602 if the delay of the delay circuit 602 is less than one-half cycle.

Returning to FIG. 6, the counter circuit 606 includes a clock input 606A and a reset input 606C. The clock input 606A is coupled to the data input terminal 404B, so that the counter circuit 606 is incremented at each rising edge of the signal D2 of the SYNC field. The counter circuit 606 includes a count output 606B, at which the counter circuit 606 provides the trim signal Trim<(n-1):0>. Thus, the counter circuit 606 generates and provides bits 0 to n-1 of the trim signal applied to the delay circuit 602, and the flip-flop 604 provides bit n of the trim signal applied to the delay circuit 602. The count output 606B of the counter circuit 606 and the output 604Q of the flip-flop 604 are coupled to the trim input 602B of the delay circuit 602.

The reset circuit 608 is coupled to the counter circuit 606, and resets the counter circuit 606 when the flip-flop 604 changes state during the SYNC field. That is, as the delay of the delay circuit 602 is adjusted, the edge of the delayed signal D1 crosses the edge of the signal D2 and the signal Trim<n> output by the flip-flop 604 changes state.

When the signal Trim<n> changes state, the reset circuit 608 detects the transition and resets the counter circuit 606. The reset circuit 608 includes an input 608A coupled to the 604Q of the flip-flop 604, and an output 608B coupled to the reset input 606C of the counter circuit 606.

The trim storage register 610 is coupled to the counter circuit 606. The trim storage register 610 stores the Trim<(n-1):0> bits generated by the counter circuit 606. More specifically, the trim storage register 610 stores, as a final trim value, the highest value of Trim<(n-1):0> (the highest count value output) produced by the counter circuit 606 during a calibration cycle (a SYNC field) (i.e., the highest value produced by the counter circuit 606 prior to being reset by the reset circuit 608). The value of Trim<(n-1):0> stored in the trim storage register 610 and the value of Trim<n> prior to the state change form the trim control signal 420 applied to trim the equalizer circuit 408, the PE delay trim circuit 416, or the delay circuits 512. The trim storage register 610 includes an input 610A coupled to the count output 606B of the 606 and a final trim output 610B coupled to the output 404C.

FIG. 8 shows an example of operation of the serial bus equalization trim circuit 600. In FIG. 8, the signals 702 and 704 represent the complementary signals D1 and D2 at the data input terminal 404A and the data input terminal 404B. The signal 802 is the delayed D1 generated by the delay circuit 602. Initially (in the example of FIG. 8), the delay provided by the delay circuit 602 is greater than one-half cycle of the signal 702, and the edge 806 of the signal 802 is later than the edge 804 of the signal 704. Accordingly, Trim<n> produced by the flip-flop 604 is a logic low, indicating that the delay of the delay circuit 602 is to be reduced, and the counter circuit 606 is incremented from 0 to 1. At edge 808 of the signal 704, the delay of the delay circuit 602 has been reduced and the edge 810 of the signal 802 is moved closer to the edge 808 of the signal 704. Trim<n> produced by the flip-flop 604 is a logic low, indicating that the delay of the delay circuit 602 is again to be reduced, and the counter circuit 606 is incremented from 1 to 2. At edge 812 of the signal 704, the delay of the delay circuit 602 has been further reduced and the edge 814 of the signal 802 occurs before the edge 812 of the signal 704. Trim<n> produced by the flip-flop 604 transitions from a logic low to a logic high, and the reset circuit 608 resets the counter circuit 606. The value of the trim control signal 420 (Trim <n:0> ) stored in the trim storage register 610 is 2.

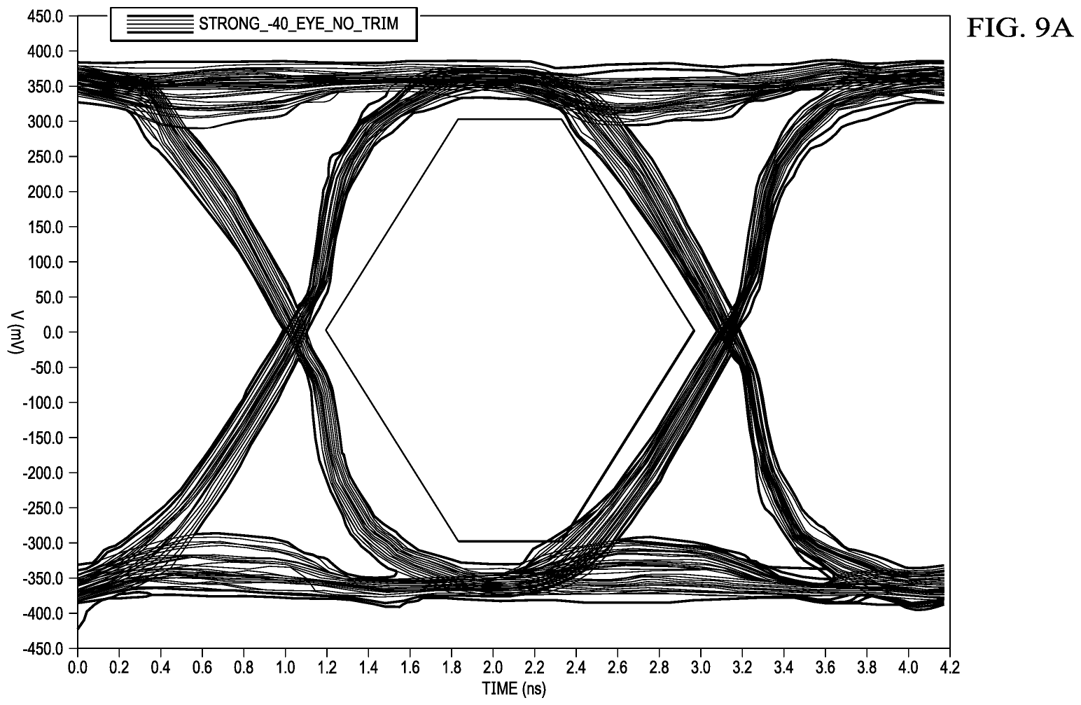

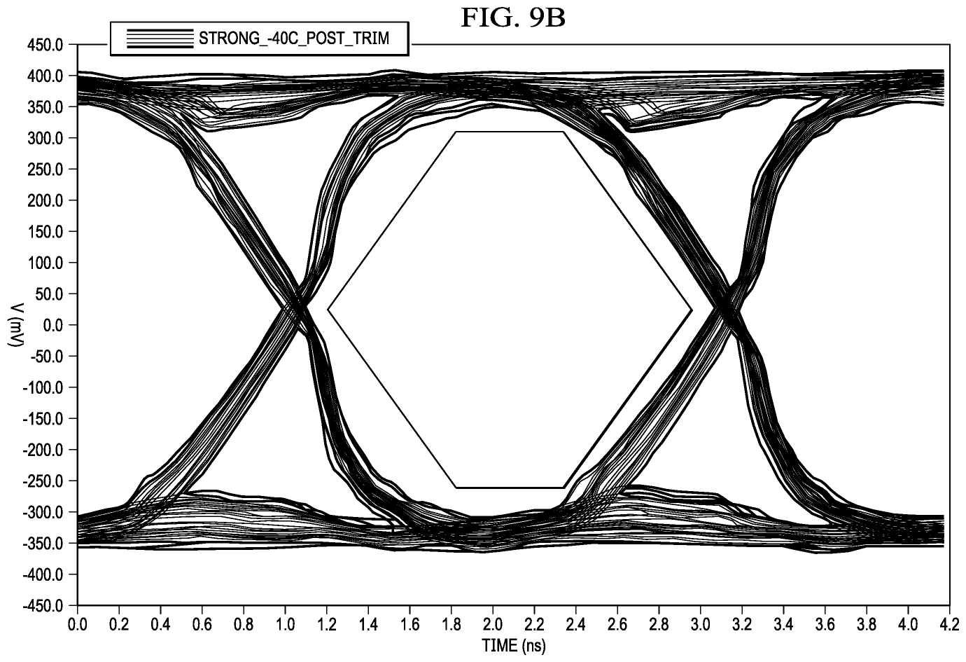

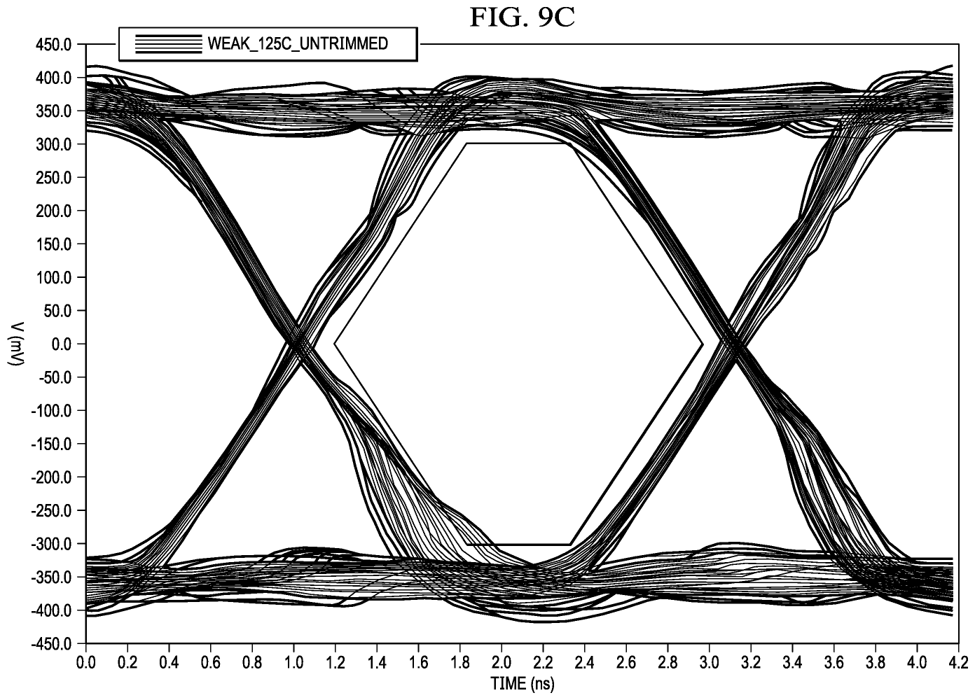

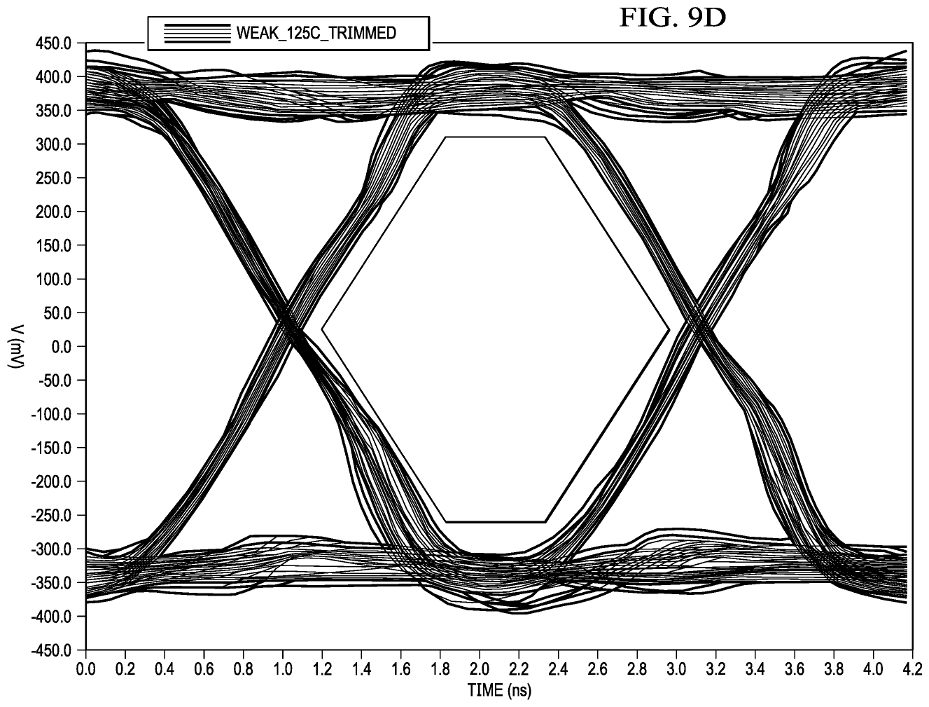

FIGS. 9A-9D show a comparison of signal eyes produced by signal conditioning circuits with and without the serial bus equalization trim circuit 600. FIGS. 9A and 9B show a comparison of strong corner results at −40° Celsius (C) produced by signal conditioning circuits without and with the serial bus equalization trim circuit 600 respectively. FIG. 9A shows increased jitter caused by boost pulse width reduction, which results in a violation of the eye specification. Jitter in FIG. 9B (with the serial bus equalization trim circuit 600) is reduced by about 15% relative to FIG. 9A, and the eye specification is not violated.

FIGS. 9C and 9D show a comparison of weak corner results at 125° C. produced by signal conditioning circuits without and with the serial bus equalization trim circuit 600 respectively. FIG. 9C shows increased jitter caused by boost pulse width increase, which results in a violation of the eye specification. Jitter in FIG. 9D (with the serial bus equalization trim circuit 600) is reduced by about 13% relative to FIG. 9C, and the eye specification is not violated.

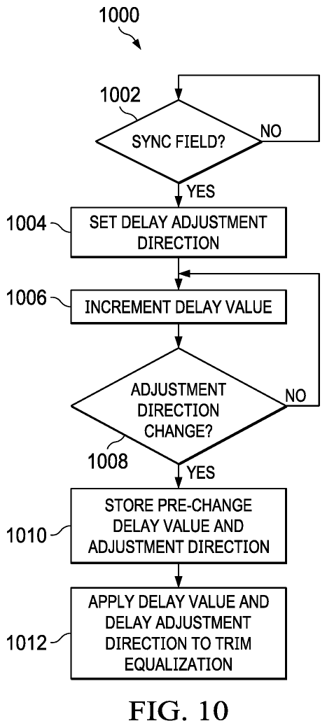

FIG. 10 show a flow diagram for an example method for trimming serial bus equalization. Though depicted sequentially as a matter of convenience, at least some of the actions shown can be performed in a different order and/or performed in parallel. Additionally, some implementations may perform only some of the actions shown. Operations of the method 1000 are performed by an implementation of the serial bus equalization trim circuit 600.

In block 1002, if a SYNC field is not being received by the serial bus equalization trim circuit 600, then the trim control signal 420 is unchanged and the serial bus equalization trim circuit 600 awaits reception of a synchronization field. If a SYNC field is being received, trim is initiated in block 1004.

In block 1004, the delayed signal D1 produced by the delay circuit 602 is clocked into the flip-flop 604 at a rising edge of the signal D2 to set the direction of delay adjustment (direction of delay change). For example, if the delay applied in the delay circuit 602 is too small, then the Trim<n> signal provided at the output 604Q of the flip-flop 604 is a logic high, and if the delay applied in the delay circuit 602 is too great, then the Trim<n> signal provided at the output 604Q of the flip-flop 604 is a logic low.

In block 1006, the delay value Trim<n-1:0> is incremented by incrementing the counter circuit 606 at the rising edge of D2. Trim<n:0> is provided to the delay circuit 602 to change the delay applied to the signal D1.

In block 1008, if the output of the flip-flop 604 (the signal at the output 604Q of the flip-flop 604) has not changed state relative to the state of the signal produced in block 1004, then delay adjustment continues in block 1006. If the signal at the output 604Q of the flip-flop 604 has changed state relative to the state produced in block 1004, then delay adjustment is complete.

In block 1010, delay adjustment is complete and the value of Trim<n:0> at the rising edge of D2 that caused the change in state of Trim<n> is stored in the trim storage register 610 for use in trimming equalization.

In block 1012, the value of Trim<n:0> stored in the trim storage register 610 is applied to trim the delay circuits 512 or to trim the equalizer circuit 408 and the PE delay trim circuit 416.

The term “couple” is used throughout the specification. The term may cover connections, communications, or signal paths that enable a functional relationship consistent with the description of the present disclosure. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A.

Modifications are possible in the described embodiments, and other embodiments are possible, within the scope of the claims.

What is claimed is:

1. A serial bus equalization trim circuit, comprising:
a first data input terminal;
a second data input terminal;
a delay circuit comprising:
a data input coupled to the first data input terminal;
a trim input; and
an output; and
a flip-flop comprising:
a data input coupled to the output of the delay circuit;
a clock input coupled to the second data input terminal; and
an output coupled to the trim input of the delay circuit.

2. The serial bus equalization trim circuit of claim 1, further comprising:
a counter circuit comprising:
a clock input coupled to the second data input terminal;
a count output coupled to the trim input of the delay circuit; and
a reset input.

3. The serial bus equalization trim circuit of claim 2, wherein the counter circuit is configured to generate a trim value that sets a delay applied in the delay circuit.

4. The serial bus equalization trim circuit of claim 2, further comprising:
a trim storage register comprising:
an input coupled to the count output of the counter circuit; and
a final trim output.

5. The serial bus equalization trim circuit of claim 4, wherein the trim storage register is configured to store a highest count value output by the counter circuit in a calibration cycle as a final trim value.

6. The serial bus equalization trim circuit of claim 2, further comprising:
a reset circuit comprising:
an input coupled to the output of the flip-flop; and
an output coupled to the reset input of the counter circuit.

7. The serial bus equalization trim circuit of claim 6, wherein the reset circuit is configured to:
detect a transition at the output of the flip-flop; and
reset the counter circuit responsive to the transition.

8. The serial bus equalization trim circuit of claim 1, wherein the flip-flop is configured to generate a delay direction signal that sets a direction of delay change in the delay circuit.

9. The serial bus equalization trim circuit of claim 1, wherein the delay circuit is configured to delay a signal received at the data input based on a signal received at the trim input.

10. A serial bus repeater circuit, comprising:
a receiver circuit comprising:
an equalizer circuit comprising a trim input; and
an amplifier coupled to the equalizer circuit, and comprising:
a first output; and
a second output; and
a serial bus equalization trim circuit comprising:
a first data input terminal coupled to the first output of the amplifier;
a second data input terminal coupled to the second output of the amplifier; and
an output coupled to the trim input of the equalizer circuit.

11. The serial bus repeater circuit of claim 10, further comprising:
a transmitter circuit comprising:
a first input coupled to the first output of the amplifier;
a second input coupled to the second output of the amplifier; and
a trim input coupled to the output of the serial bus equalization trim circuit to control a width of post cursor emphasis.

12. The serial bus repeater circuit of claim 10, wherein the serial bus equalization trim circuit further comprises:
a delay circuit comprising:
a data input coupled to the first data input terminal;
a trim input; and
an output; and
a flip-flop comprising:
a data input coupled to the output of the delay circuit;
a clock input coupled to the second data input terminal; and
an output coupled to the trim input of the delay circuit.

13. The serial bus repeater circuit of claim 12, wherein the serial bus equalization trim circuit further comprises:
a counter circuit comprising:
a clock input coupled to the second data input terminal;
a count output coupled to the trim input of the delay circuit; and
a reset input.

14. The serial bus repeater circuit of claim 13, wherein the serial bus equalization trim circuit further comprises:
a trim storage register comprising:
an input coupled to the count output of the counter circuit; and
a final trim output coupled to the output of the serial bus equalization trim circuit.

15. The serial bus repeater circuit of claim 13, wherein the serial bus equalization trim circuit further comprises:
a reset circuit comprising:
an input coupled to the output of the flip-flop; and
an output coupled to the reset input of the counter circuit.

16. A serial bus signal conditioner circuit, comprising:
a first serial bus terminal;
a second serial bus terminal;
an edge detector circuit comprising:
a first input coupled to the first serial bus terminal;
a second input coupled to the second serial bus terminal; and
a first output; and
a second output;
a booster circuit comprising:
a first input coupled to the first output of the edge detector circuit;
a second input coupled to the second output of the edge detector circuit;
a first output coupled to the first serial bus terminal;
a second output coupled to the second serial bus terminal; and
a trim input; and
a serial bus equalization trim circuit comprising:
a first data input terminal coupled to the first output of the edge detector circuit;
a second data input terminal coupled to the second output of the edge detector circuit; and
an output coupled to the trim input of the booster circuit.

17. The serial bus signal conditioner circuit of claim 16, wherein the serial bus equalization trim circuit further comprises:
a delay circuit comprising:
a data input coupled to the first data input terminal;
a trim input; and
an output;
a flip-flop comprising:
a data input coupled to the output of the delay circuit;
a clock input coupled to the second data input terminal; and
an output coupled to the trim input of the delay circuit; and
a counter circuit comprising:
a clock input coupled to the second data input terminal;
a count output coupled to the trim input of the delay circuit; and
a reset input.

18. The serial bus signal conditioner circuit of claim 17, wherein the serial bus equalization trim circuit further comprises:
a trim storage register comprising:
an input coupled to the count output of the counter circuit; and
a final trim output coupled to the output of the serial bus equalization trim circuit.

19. The serial bus signal conditioner circuit of claim 17, wherein the serial bus equalization trim circuit further comprises:
a reset circuit comprising:
an input coupled to the output of the flip-flop; and
an output coupled to the reset input of the counter circuit.

20. The serial bus signal conditioner circuit of claim 16, wherein the booster circuit comprises:
a delay circuit comprising an input coupled to the output of the serial bus equalization trim circuit.
